(19) United States
(12) Patent Application Publication
(10) Pub. No.: US 2025/0359046 A1
(43) Pub. Date: Nov. 20, 2025

(54) SPLIT-GATE NON-VOLATILE MEMORY ARRAY WITH BIDIRECTIONAL OPERATION

(71) Applicant: Silicon Storage Technology, Inc., San Jose, CA (US)

(72) Inventors: Jeng-Wei Yang, Zhubei City (TW); Man-Tang Wu, Hsinchu (TW); Hieu Van Tran, San Jose, CA (US); Xian Liu, Sunnyvale, CA (US); Nhan Do, Saratoga, CA (US)

(21) Appl. No.: 18/810,437

(22) Filed: Aug. 20, 2024

Related U.S. Application Data
(60) Provisional application No. 63/649,257, filed on May 17, 2024.

(51) Int. Cl. H10B 41/30; H01L 29/423; H01L 29/788; H10B 41/10

(52) U.S. Cl. CPC H10B 41/30; H10B 41/10; H10D 30/685; H10D 30/6892

(57) ABSTRACT

A semiconductor device with interleaved active and isolation regions extending in a first direction. Memory cells formed in the active regions each include first and second drain regions, first and second floating gates, word line gate, first and second control gates, and first and second erase gates. Each of the active regions includes a plurality of first drain contacts each electrically connected to one of the first drain regions in the active region, and a plurality of second drain contacts each electrically connected to one of the second drain regions in the active region. A plurality of first bit lines extend in the first direction and each is electrically connected to the first drain contacts in one of the active regions. A plurality of second bit lines extend in the first direction and each is electrically connected to the second drain contacts in two of the active regions.

### RELATED APPLICATIONS

This application claims the benefit of U.S. Provisional Application No. 63/649,257, filed May 17, 2024, and which is incorporated herein by reference.

### FIELD OF THE INVENTION

The present invention relates to non-volatile memory arrays.

### BACKGROUND OF THE INVENTION

Split gate non-volatile flash memory cells are well known. For example, U.S. Pat. No. 6,747,310 discloses such memory cells having source and drain regions defining a channel region there between, a select gate over one portion of the channel region, a floating gate over the other portion of the channel region, and an erase gate over the source region. The memory cells are formed in pairs that share a common source region and common erase gate, with each memory cell having its own channel region in the substrate extending between the source and drain regions (i.e. there are two separate channel regions for each pair of memory cells).

Given the number of electrodes for each cell (source, drain, select gate, control gate and erase gate), and two separate channel regions for each pair of memory cells (one channel region for each memory cell), configuring and forming the architecture and array layout with all the various lines connected to these electrodes can be overly complex and difficult to implement, especially as critical dimensions continue to shrink.

U.S. Pat. No. 11,849,577 discloses a memory cell configuration and array layout that utilizes a virtual ground memory cell configuration, where a pair of memory cells are disposed over a single continuous channel region that extends between two drain regions. The pair of memory cells includes two floating gates and a word line gate disposed over (and control the conductivity of) three different portions, respectively, of the continuous channel region. Control gates are disposed over the floating gates, and erase gates are disposed over the drain regions.

There is a need to improve the performance and manufacturing reliability of the virtual ground memory cells as the memory cell components are scaled down in size.

### BRIEF SUMMARY OF THE INVENTION

The aforementioned problems and needs are addressed by a semiconductor device that comprises:
a semiconductor substrate having a first conductivity type;
isolation regions formed on the semiconductor substrate which are parallel to one another and extend in a first direction, with an active region between each pair of adjacent isolation regions also extending in the first direction;
wherein each of the active regions includes a plurality of pairs of memory cells, and wherein each of the pair of memory cells includes:
   a first drain region and a second drain region in the semiconductor substrate and having a second conductivity type different than the first conductivity type, with a continuous channel region in the semiconductor substrate extending between the first drain region and the second drain region,
   a first floating gate disposed over and insulated from a first portion of the channel region adjacent to the first drain region,
   a second floating gate disposed over and insulated from a second portion of the channel region adjacent to the second drain region,
   a word line gate disposed over and insulated from a third portion of the channel region that is between the first portion of the channel region and the second portion of the channel region,
   a first control gate disposed over and insulated from the first floating gate,
   a second control gate disposed over and insulated from the second floating gate,
   a first erase gate disposed over and insulated from the first drain region, and
   a second erase gate disposed over and insulated from the second drain region;
wherein for each one of the pair of memory cells in one of the active regions:
   the channel region extends in the first direction from the first drain region to the second drain region,
   the first drain region of the one pair of memory cells is the first drain region of an adjacent pair of memory cells in the one active region, and
   the second drain region of the one pair of memory cells is the second drain region of an adjacent pair of memory cells in the one active region;
a plurality of first control gate lines extending in the second direction orthogonal to the first direction and each electrically connected to one of the first control gates in each of the active regions;
a plurality of second control gate lines extending in the second direction and each electrically connected to one of the second control gates in each of the active regions;
a plurality of first erase gate lines extending in the second direction and each electrically connected to one of the first erase gates in each of the active regions;
a plurality of second erase gate lines extending in the second direction and each electrically connected to one of the second erase gates in each of the active regions;
a plurality of word lines extending in the second direction and each electrically connected to one of the word line gates in each of the active regions;
each of the active regions includes a plurality of first drain contacts each electrically connected to one of the first drain regions in the active region, and a plurality of second drain contacts each electrically connected to one of the second drain regions in the active region;
a plurality of first bit lines extending in the first direction and each electrically connected to the first drain contacts in one of the active regions; and a plurality of second bit lines extending in the first direction and each electrically connected to the second drain contacts in two of the active regions.

A semiconductor device, comprises:
a semiconductor substrate having a first conductivity type;
isolation regions formed on the semiconductor substrate which are parallel to one another and extend in a first direction, with an active region between each pair of adjacent isolation regions also extending in the first direction;
wherein each of the active regions includes a plurality of pairs of memory cells, and wherein each of the pair of memory cells includes:
   a first drain region and a second drain region in the semiconductor substrate and having a second conductivity type different than the first conductivity type, with a continuous channel region in the semiconductor substrate extending between the first drain region and the second drain region,
   a first floating gate disposed over and insulated from a first portion of the channel region adjacent to the first drain region,
   a second floating gate disposed over and insulated from a second portion of the channel region adjacent to the second drain region,
   a word line gate disposed over and insulated from a third portion of the channel region that is between the first portion of the channel region and the second portion of the channel region,
   a first control gate disposed over and insulated from the first floating gate,
   a second control gate disposed over and insulated from the second floating gate,
   a first erase gate disposed over and insulated from the first drain region, and
   a second erase gate disposed over and insulated from the second drain region;
wherein for each one of the pair of memory cells in one of the active regions:
   the channel region extends in the first direction from the first drain region to the second drain region,
   the first drain region of the one pair of memory cells is the first drain region of an adjacent pair of memory cells in the one active region, and
   the second drain region of the one pair of memory cells is the second drain region of an adjacent pair of memory cells in the one active region;
a plurality of first control gate lines extending in the second direction orthogonal to the first direction and each electrically connected to one of the first control gates in each of the active regions;
a plurality of second control gate lines extending in the second direction and each electrically connected to one of the second control gates in each of the active regions;
a plurality of first erase gate lines extending in the second direction and each electrically connected to one of the first erase gates in each of the active regions;
a plurality of second erase gate lines extending in the second direction and each electrically connected to one of the second erase gates in each of the active regions;
a plurality of word lines extending in the second direction and each electrically connected to one of the word line gates in each of the active regions;
each of the active regions includes a plurality of first drain contacts each electrically connected to one of the first drain regions in the active region, and a plurality of second drain contacts each electrically connected to one of the second drain regions in the active region;
wherein for each one of the active regions:
   each of the first drain contacts in the one active region is electrically connected to one of the first drain contacts in a second one of the active regions adjacent to the one active region by a first connector, and
   each of the second drain contacts in the one active region is electrically connected to one of the second drain contacts in a third one of the active regions adjacent to the one active region by a second connector;
wherein the active regions comprise first active regions and second active regions, wherein the first active regions alternate with the second active regions;
a plurality of first bit lines each extending over one of the first active regions and electrically connected to the first connectors that are electrically connected to the first drain contacts of the one first active region; and
a plurality of second bit lines each extending over one of the second active regions and electrically connected to the second connectors that are electrically connected to the second drain contacts of the one second active region.

Other objects and features of the present disclosure will become apparent by a review of the specification, claims and appended figures.

### BRIEF DESCRIPTION OF THE DRAWINGS

FIG. 1 is a side cross section view of memory cells.

FIG. 2 is a top layout view illustrating an architecture of an array of the memory cells of FIG. 1.

FIG. 3 is a table showing examples of voltages for programming, erasing and reading the memory cells of FIG. 1.

FIG. 4 is a table showing examples of voltages for programming, erasing and reading the memory cells of FIG. 1.

FIG. 5 is a top layout view illustrating an architecture of an array of the memory cells of FIG. 1.

### DETAILED DESCRIPTION OF THE INVENTION

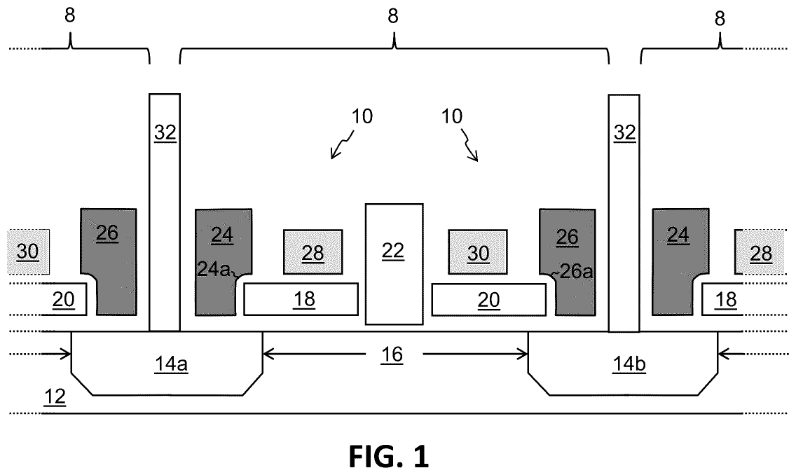

Described herein is an example of a semiconductor device 1 with columns of memory cells formed end to end. FIG. 1 illustrates a pair of memory cells 8 that includes two memory cells 10 formed over a semiconductor substrate 12 of a first conductivity type (e.g. n+) with first and second drain regions 14a, 14b of a second conductivity type (e.g., p+), and with a single, continuous channel region 16 of the semiconductor substrate 12 extending between the first drain region 14a and the second drain region 14b. Each pair of memory cells 8 includes a first floating gate 18 disposed over and insulated from (for controlling the conductivity of) a first portion of the continuous channel region 16, a second floating gate 20 disposed over and insulated from (for controlling the conductivity of) a second portion of the continuous channel region 16, and a word line gate 22 disposed over and insulated from (for controlling the conductivity of) a third portion of the continuous channel region 16 that is between the first and second portions of the continuous channel region (i.e., the word line gate 22 is disposed between the first floating gate 18 and the second floating gate 20). A first erase gate 24 is disposed over and insulated from first drain region 14a and a second erase gate 26 is disposed over and insulated from the second drain region 14b. First and second erase gates 24, 26 include first and second cavities 24a, 26a that face edges of the respective first and second floating gates 18, 20 to enhance erase efficiency. A first control gate 28 is disposed over and insulated from the first floating gate 18. A second control gate 30 is disposed over and insulated from the second floating gate 20. Each pair of memory cells 8 includes two memory cells 10 that share a common word line gate 22 and a common continuous channel region 16. Each of the drain regions 14a, 14b includes a drain contact 32 in electrical contact thereto. Adjacent pairs of memory cells 8 share a common drain region 14a or 14b, and a common drain contact 32 that is in electrical contact with the respective drain region 14a, 14b.

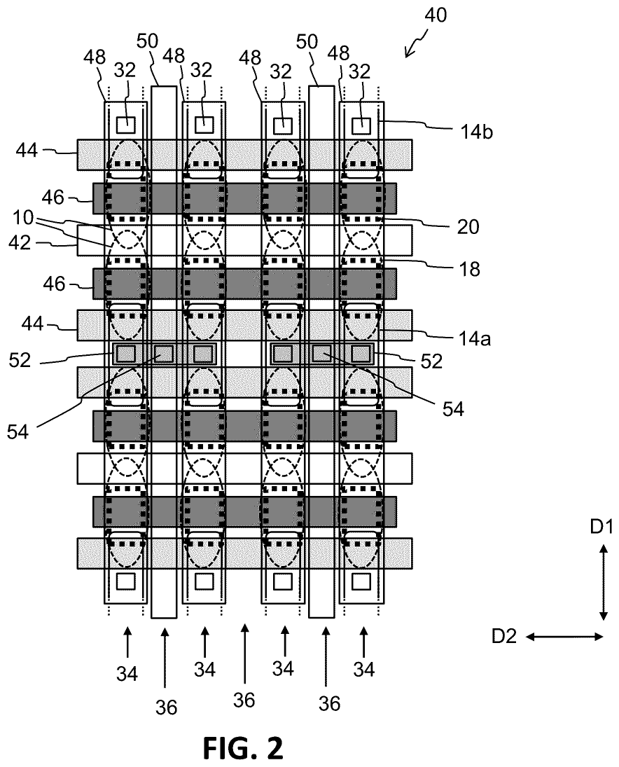

FIG. 2 shows a layout and architecture for an array 40 of the memory cells 10. While only four columns and four rows of memory cells 10 are shown, it should be understood that what is shown can be only part of a larger array of the memory cells 10. The semiconductor substrate 12 includes alternating active regions 34 and isolation regions 36 that have lengths extending in a parallel manner in a first direction D1 (e.g., a column direction). Each of the isolation regions 36 can include a trench formed into the upper surface of the semiconductor substrate 12, which is filled with insulation material such as oxide (i.e., silicon oxide, silicon dioxide, or a combination of both). Each isolation region 36 is between two adjacent active regions 34 to provide isolation between the adjacent active regions 34, and therefore each active region 34 is between two adjacent isolation regions 34. The pairs of memory cells 8 are formed end to end in the active regions 34, such that memory cells 10 are arranged in rows and columns of the memory cells 10. Therefore, the drain contacts 32 are also arranged in rows and columns of the drain contacts 32. In each active region 34, pairs of memory cells 8 are arranged end to end so that for any given pair of memory cells 8, its first drain region 14a is the first drain region 14a of an adjacent pair of memory cells 8 in the same active region 34, and its second drain region 14b is the second drain region 14b of the other adjacent pair of memory cells 8 in the same active region.

The array 40 includes word lines 42 which extend in a second direction D2 (e.g., a row direction) orthogonal to the first direction. Each of the word lines 42 electrically connects together all the word line gates 22 for one of the rows of the pairs of memory cells 8 (i.e., one word line gate 22 from each active region 34). Each of the word lines 42 can be a first strip of conductive material that extends in the row direction across the active regions 34 and isolation regions 36, whereby the portion of the first strip of conductive material that extends across any given pair of memory cells 8 constitutes the word line gate 22 for that pair of memory cells 8.

Erase gate lines 44 extend in the second direction D2. Each of the erase gate lines 44 electrically connects together all the erase gates 24 or 26 for a row of the memory cells 10 (i.e., one erase gate 24, 26 from each active region 34). Each of the erase gate lines 44 can be a second strip of conductive material that extends in the row direction across the active regions 34 and isolation regions 36, whereby the portion of the second strip of conductive material that extends across any given memory cell 10 constitutes the erase gate 24 or 26 for that memory cell 10.

Control gate lines 46 extend in the second direction D2. Each of the control gate lines 46 electrically connects together all the control gates 28 or 30 for a row of the memory cells 10 (i.e., one control gate 28, 30 from each active region 34). Each of the control gate lines 46 can be a third strip of conductive material that extends in the row direction across the active regions 34 and isolation regions 36, whereby the portion of the third strip of conductive material that extends across any given memory cell 10 constitutes the control gate 28 or 30 for that memory cell 10.

First bit lines 48 extend in the first direction D1 over the active regions. Each of the first bit lines 48 electrically connects together the drain contacts 32 (and therefore the drain regions 14a, 14b connected thereto) for alternating ones (e.g., even rows or odd rows) of the drain contacts 32 in a column of the memory cells 10. Each of the first bit lines 48 can be a fourth strip of conductive material that extends in the column direction along one of the active regions 34 and is in electrical contact with even rows or odd rows of the drain contacts 32 for the column of the memory cells 10 in that active region 34. As a non-limiting example, if the top row of drain contacts 32 in FIG. 1 is considered row 1 of the drain contacts 32, then each of the first bit lines 48 electrically connect together odd rows of the drain contacts 32 in one of the columns of the memory cells 10.

Second bit lines 50 extend in the first direction D1. Each of the second bit lines 50 are disposed over one of the isolation regions 36 and are electrically connected to alternating ones (e.g., odd rows or even rows) of the drain contacts 32 in the two adjacent active regions 34 on either side of the second bit line 50 by connectors 52 and contacts 54. Connectors 52 and contacts 54 are not located in the rows of the drain contacts 32 that are connected to the first bit lines 48. Each of the second bit lines 50 can be a fifth strip of conductive material that extends in the column direction over one of the isolation regions 36. Second bit lines 50 are disposed over every other isolation region 36 in an alternating fashion, and electrically connected to drain contacts 32 in the two adjacent active regions 34. As a non-limiting example, if the top row of drain contacts 32 in FIG. 1 is considered row 1 of the drain contacts 32, then each of the second bit lines 48 electrically connect together even rows of the drain contacts 32 in two adjacent columns of the memory cells 10. The current path for any given memory cell 10 can be from one of the first bit lines 48, through one of the drain contacts 32, through the continuous channel regions 16 of the given memory cell 10, through one of the drain contacts 32, through one of the connectors 52, through one of the contacts 54, and to one of the second bit lines 50.

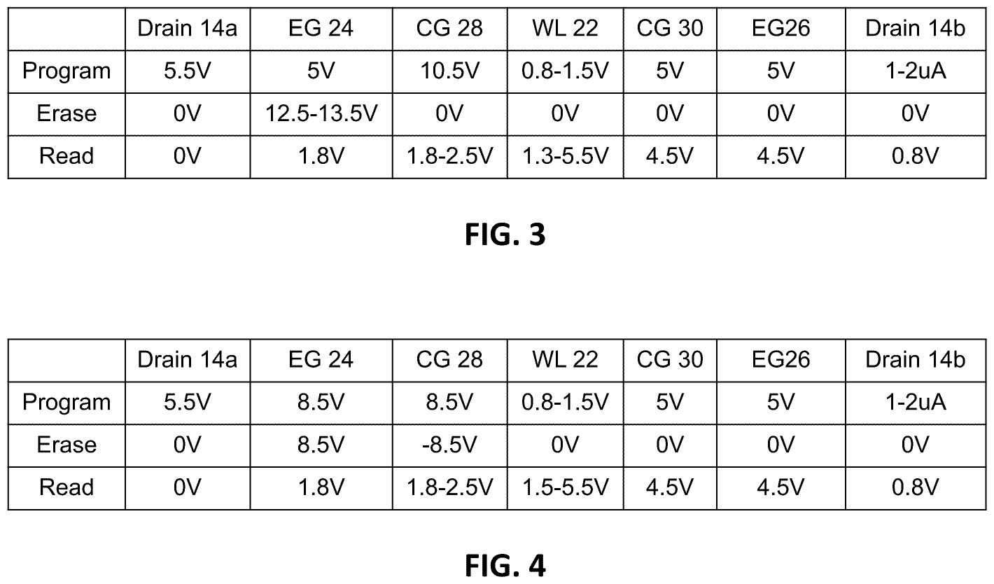

FIG. 3 is a table showing examples of voltages to be applied to the pair of memory cells 8 of FIG. 1 to program, erase and read first floating gate 18. When the voltages for program set forth in FIG. 3 are applied, electrons flow from second drain region 14b along continuous channel region 16 until they reach first floating gate 18, where some of the electrons become heated and are injected onto first floating gate 18 (i.e. by hot electron injection). When the voltages for erase set forth in FIG. 3 are applied, electrons on floating gate 18 tunnel through the insulation and onto first erase gate 24. When the voltages for read set forth in FIG. 3 are applied, the portions of the continuous channel region 16 under the word line gate 22 and the second floating gate 20 are conductive. If the first floating gate 18 is programmed with electrons (i.e., has a relatively negative charge), the portion of the continuous channel region 16 under the first floating gate 18 will have a low conductivity and therefore the current through the continuous channel region 16 will be low. If the first floating gate 18 is not programmed with electrons (i.e., has a relatively positive charge), the portion of the continuous channel region 16 under the first floating gate 18 will have a high conductivity and therefore the current through the continuous channel region 16 will be high. The sensed current level (either low or high) through the continuous channel region 16 during the read operation is indicative of the program state of the first floating gate 18 (i.e., a low current can be sensed to be data bit “0” and a high current can be sensed to be data bit “1”). To program, erase and read the second floating gate 20, the voltages/current on the first and second drain regions 14a, 14b, the voltages on the first and second erase gates 24, 26, and the voltages on first and second control gates 28, 30, can be reversed, respectively. FIG. 4 is a table showing another set of examples of voltages to be applied to the pair of memory cells 8 of FIG. 1 to program, erase and read first floating gate 18.

The array 40 of memory cells 10 have many advantages. Each pair of memory cells 8 includes a single, continuous channel region 16 and a shared word line gate 22, so the memory cells 10 and the array 40 can be more easily scaled down in size. A drain contact 32 is provided for each drain region 14a, 14b (which are shared among adjacent pairs of memory cells 8). Drain contacts 32 provide a better conduction path for voltage and current distribution to each drain region 14a, 14b, without reliance on higher resistance diffusion lines in the semiconductor substrate 12. Moreover, diffusion lines in the isolation regions 36 connecting various drain regions 14a, 14b together is avoided, thereby increasing the isolation between adjacent active regions 34 provided by the isolation regions 36. The word lines 42, erase gate lines 44 and control gate lines 46 all extend in the row direction, parallel to each other, to reduce the risk of any of these lines shorting together. Each pair of memory cells 8 includes two erase gates 24, 26, which are not shared with the adjacent pair of memory cells 8 in the same active region 34, to provide independent erase operations for each memory cell 10 in the pair of memory cells 8. Each of the second bit lines provides a conduction path for voltage and current distribution to a pair of memory cell columns (i.e., via a pair of the first bit lines 48), to simplify the operation of the memory array.

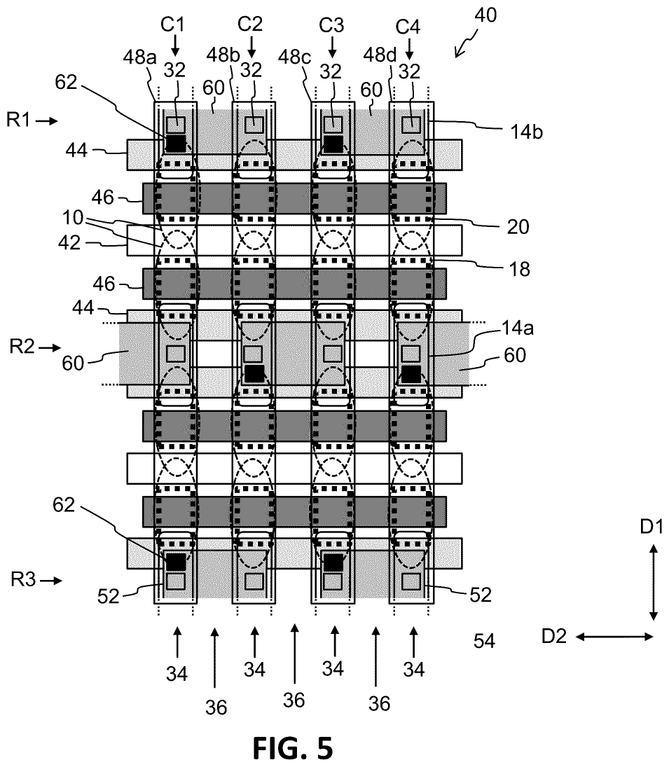

FIG. 5 illustrates another example which is similar to that shown in FIG. 2, but instead of second bit lines 50, connectors 52 and contacts 54, each row of drain contacts 32 includes connectors 60, where each connector 60 electrically connects together a pair of drain contacts 32 from two adjacent columns of memory cells 10. Respective rows of connectors 60 are staggered in an alternating manner with respect to which columns of memory cells 10 have their drain contacts 32 connected together. For example, FIG. 5 illustrates four columns of drain contacts 32 labeled C1, C2, C3, C4, and the three rows of drain contacts 32 labeled R1, R2, R3. For row R1, the drain contact 32 for column C2 is connected to the drain contact for column C1 (i.e., the column to the left of column C2) by a connector 60. For row R2, the drain contact 32 for column C2 is connected to the drain contact for column C3 (i.e., the column to the right of column C2) by a connector 60. For row R3, the drain contact 32 for column C2 is connected to the drain contact for column C1 (i.e., the column to the left of column C2) by a connector 60, and so on. In addition, each connector 60 is connected to one of the first bit lines 48 by a contact 62, which are also staggered in an alternating manner. For row R1, the connectors 60 are connected to first bit lines 48a and 48c by contacts 62. For row R2, connectors 60 are connected to first bit lines 48b and 48d by contacts 62. For row R3, the connectors 60 are connected to first bit lines 48a and 48c by contacts 62, and so on. Therefore, each first bit line 48 is electrically connected to every other row of connectors 60. The current path for any given memory cell 10 can be from one of the first bit lines 48a-48d, through one of the contacts 62, through one of the connectors 60, through one of the drain contacts 32, through the continuous channel regions 16 of the given memory cell 10, through another one of the drain contacts 32, through another one of the connectors 60, through another one of the contacts 62, and to another one of the first bit lines 48a-48d.

Explaining the non-limiting example of FIG. 5 another way, each of the active regions 34 includes a plurality of first drain contacts 32 (i.e., a first plurality of the drain contacts 32) each electrically connected to one of the first drain regions 14a in the active region 34, and a plurality of second drain contacts 32 (i.e., a second plurality of the drain contacts 32) each electrically connected to one of the second drain regions 14b in the active region 34. For each of the active regions, each of the first drain contacts 32 in the one active region 34 is electrically connected to one of the first drain contacts 32 in a second one of the active regions 34 adjacent to the one active region by a first connector 52 (i.e., connectors 52 are either first connectors 52 or second connectors 52), and each of the second drain contacts 32 in the one active region is electrically connected to one of the second drain contacts 32 in a third one of the active regions 34 adjacent to the one active region 34 by a second connector 52. The active regions 34 can comprise first active regions 34 and second active regions 34, wherein the first active regions 34 alternate with the second active regions 34. A plurality of first bit lines (e.g. bit lines 48a, 48c, etc.) each extend over one of the first active regions and are electrically connected to the first connectors 52 that are electrically connected to the first drain contacts 32 of the one first active region. A plurality of second bit lines (e.g., bit lines 48b, 48d, etc.) each extend over one of the second active regions 34 and are electrically connected to the second connectors 52 that are electrically connected to the second drain contacts 32 of the one second active region.

It is to be understood that the present disclosure is not limited to the example(s) described above and illustrated herein, but encompasses any and all variations falling within the scope of any claims. For example, references to the present disclosure or invention or examples herein are not intended to limit the scope of any claim or claim term, but instead merely make reference to one or more features that may be covered by one or more claims. Materials, processes and numerical examples described above are exemplary only, and should not be deemed to limit the claims. Further, as is apparent from the claims and specification, not all method operations need be performed in the exact order illustrated or claimed, but rather in any order (unless there is an explicitly recited limitation on any order) that allows the proper formation of the semiconductor device described herein. Single layers of material could be formed as multiple layers of such or similar materials, and vice versa. Lastly, the terms “forming” and “formed” as used herein shall include material deposition, material growth, or any other technique in providing the material as disclosed or claimed.

It should be noted that, as used herein, the terms “over” and “on” both inclusively include “directly on” (no intermediate materials, elements or space disposed there between) and “indirectly on” (intermediate materials, elements or space disposed there between). Likewise, the term “adjacent” includes “directly adjacent” (no intermediate materials, elements or space disposed there between) and “indirectly adjacent” (intermediate materials, elements or space disposed there between), “mounted to” includes “directly mounted to” (no intermediate materials, elements or space disposed there between) and “indirectly mounted to” (intermediate materials, elements or spaced disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a semiconductor substrate” can include forming the element directly on the semiconductor substrate with no intermediate materials/elements there between, as well as forming the element indirectly on the semiconductor substrate with one or more intermediate materials/elements there between. Finally, the claims are comprising claims unless otherwise stated, and therefore “each” of a plurality of elements having a limitation does not preclude the inclusion of additional such elements lacking the limitation unless otherwise specifically claimed.

What is claimed is:

1. A semiconductor device, comprising:
a semiconductor substrate having a first conductivity type;
isolation regions formed on the semiconductor substrate which are parallel to one another and extend in a first direction, with an active region between each pair of adjacent isolation regions also extending in the first direction;
wherein each of the active regions includes a plurality of pairs of memory cells, and wherein each of the pair of memory cells includes:
a first drain region and a second drain region in the semiconductor substrate and having a second conductivity type different than the first conductivity type, with a continuous channel region in the semiconductor substrate extending between the first drain region and the second drain region,
a first floating gate disposed over and insulated from a first portion of the channel region adjacent to the first drain region,
a second floating gate disposed over and insulated from a second portion of the channel region adjacent to the second drain region,
a word line gate disposed over and insulated from a third portion of the channel region that is between the first portion of the channel region and the second portion of the channel region,
a first control gate disposed over and insulated from the first floating gate,
a second control gate disposed over and insulated from the second floating gate,
a first erase gate disposed over and insulated from the first drain region, and
a second erase gate disposed over and insulated from the second drain region;
wherein for each one of the pair of memory cells in one of the active regions:
the channel region extends in the first direction from the first drain region to the second drain region,
the first drain region of the one pair of memory cells is the first drain region of an adjacent pair of memory cells in the one active region, and
the second drain region of the one pair of memory cells is the second drain region of an adjacent pair of memory cells in the one active region;
a plurality of first control gate lines extending in the second direction orthogonal to the first direction and each electrically connected to one of the first control gates in each of the active regions;
a plurality of second control gate lines extending in the second direction and each electrically connected to one of the second control gates in each of the active regions;
a plurality of first erase gate lines extending in the second direction and each electrically connected to one of the first erase gates in each of the active regions;
a plurality of second erase gate lines extending in the second direction and each electrically connected to one of the second erase gates in each of the active regions;
a plurality of word lines extending in the second direction and each electrically connected to one of the word line gates in each of the active regions;
each of the active regions includes a plurality of first drain contacts each electrically connected to one of the first drain regions in the active region, and a plurality of second drain contacts each electrically connected to one of the second drain regions in the active region;
a plurality of first bit lines extending in the first direction and each electrically connected to the first drain contacts in one of the active regions; and
a plurality of second bit lines extending in the first direction and each electrically connected to the second drain contacts in two of the active regions.

2. The semiconductor device of claim 1, wherein:
each of first bit lines is disposed over one of the active regions; and
each of the second bit lines is disposed over one of the isolation regions.

3. The semiconductor device of claim 1, comprising:
a plurality of connectors each electrically connected to one of the second drain contacts in one of the active regions and one of the second drain contacts in another one of the active regions; and
a plurality of contacts electrically connected between one of the connectors and one of the second bit lines.

4. A semiconductor device, comprising:
a semiconductor substrate having a first conductivity type;
isolation regions formed on the semiconductor substrate which are parallel to one another and extend in a first direction, with an active region between each pair of adjacent isolation regions also extending in the first direction;
wherein each of the active regions includes a plurality of pairs of memory cells, and wherein each of the pair of memory cells includes:
a first drain region and a second drain region in the semiconductor substrate and having a second conductivity type different than the first conductivity type, with a continuous channel region in the semiconductor substrate extending between the first drain region and the second drain region,
a first floating gate disposed over and insulated from a first portion of the channel region adjacent to the first drain region,
a second floating gate disposed over and insulated from a second portion of the channel region adjacent to the second drain region,
a word line gate disposed over and insulated from a third portion of the channel region that is between the first portion of the channel region and the second portion of the channel region,
a first control gate disposed over and insulated from the first floating gate,
a second control gate disposed over and insulated from the second floating gate,
a first erase gate disposed over and insulated from the first drain region, and
a second erase gate disposed over and insulated from the second drain region;
wherein for each one of the pair of memory cells in one of the active regions:
the channel region extends in the first direction from the first drain region to the second drain region,
the first drain region of the one pair of memory cells is the first drain region of an adjacent pair of memory cells in the one active region, and
the second drain region of the one pair of memory cells is the second drain region of an adjacent pair of memory cells in the one active region;
a plurality of first control gate lines extending in the second direction orthogonal to the first direction and each electrically connected to one of the first control gates in each of the active regions;
a plurality of second control gate lines extending in the second direction and each electrically connected to one of the second control gates in each of the active regions;
a plurality of first erase gate lines extending in the second direction and each electrically connected to one of the first erase gates in each of the active regions;
a plurality of second erase gate lines extending in the second direction and each electrically connected to one of the second erase gates in each of the active regions;
a plurality of word lines extending in the second direction and each electrically connected to one of the word line gates in each of the active regions;
each of the active regions includes a plurality of first drain contacts each electrically connected to one of the first drain regions in the active region, and a plurality of second drain contacts each electrically connected to one of the second drain regions in the active region;
wherein for each one of the active regions:
each of the first drain contacts in the one active region is electrically connected to one of the first drain contacts in a second one of the active regions adjacent to the one active region by a first connector, and
each of the second drain contacts in the one active region is electrically connected to one of the second drain contacts in a third one of the active regions adjacent to the one active region by a second connector;
wherein the active regions comprise first active regions and second active regions, wherein the first active regions alternate with the second active regions;
a plurality of first bit lines each extending over one of the first active regions and electrically connected to the first connectors that are electrically connected to the first drain contacts of the one first active region; and
a plurality of second bit lines each extending over one of the second active regions and electrically connected to the second connectors that are electrically connected to the second drain contacts of the one second active region.
